(19) United States
(12) Patent Application Publication
(10) Pub. No.: US 2017/0275172 A1
(43) Pub. Date: Sep. 28, 2017

(54) SODIUM ANTI-PEROVSKITE SOLID ELECTROLYTE COMPOSITIONS

(71) Applicant: THE BOARD OF REGENTS OF THE NEVADA SYSTEM OF HIGHER EDUCATION ON BEHALF OF THE UNIVERSITY OF NE, Las Vegas, NV (US)

(72) Inventors: Yusheng ZHAO, Las Vegas, NV (US); Yonggang WANG, Argonne, IL (US); Ruqiang ZOU, Beijing (CN)

(21) Appl. No.: 15/505,890

(22) PCT Filed: Aug. 22, 2014
(86) PCT No.: PCT/CN2014/084981

§ 371 Date: Feb. 22, 2017

(51) Int. Cl. C01D 3/04; H01G 9/00; H01M 10/054; C01B 11/22; C30B 29/12; C30B 11/00; C01B 11/06; C01B 11/20; H01G 9/032; H01M 10/0562

(52) U.S. Cl. CPC C01D 3/04; H01G 9/032; H01G 9/0036; H01M 10/054; H01M 10/0562; C30B 29/12; C30B 11/003; C01B 11/062; C01B 11/20; C01B 11/064; C01B 11/22; H01M 2300/0071; H01M 2300/008; C01P 2002/30; C01P 2006/40; C01P 2002/77; C01P 2002/72; C01P 2002/88

(57) ABSTRACT

Na-rich electrolyte compositions provided herein can be used in a variety of devices, such as sodium ionic batteries, capacitors and other electrochemical devices. Na-rich electrolyte compositions provided herein can have a chemical formula of Na₃OX, Na₃SX, Na _{(3-δ)} M_{δ/2}OX and Na _{(3-δ)} M_{δ/2}SX wherein 0<δ<0.8, wherein X is a monovalent anion selected from fluoride, chloride, bromide, iodide, H⁻, CN⁻, BF₄⁻, BH₄⁻, ClO₄⁻, CH₃⁻, NO₂⁻, NH₂⁻ and mixtures thereof, and wherein M is a divalent metal selected from the group consisting of magnesium, calcium, barium, strontium and mixtures thereof. Na-rich electrolyte compositions provided herein can have a chemical formula of Na _{(3-δ)} M_{δ/3}OX and/or Na _{(3-δ)} M_{δ/3}SX; wherein 0<δ<0.5, wherein M is a trivalent cation M³, and wherein X is selected from fluoride, chloride, bromide, iodide, H⁻, CN⁻, BF₄⁻, BH₄⁻, ClO₄⁻, CH₃⁻, NO₂⁻, NH²⁻ and mixtures thereof. Synthesis and processing methods of NaRAP compositions for battery, capacitor, and other electrochemical applications are also provided.

### STATEMENT REGARDING FEDERAL RIGHTS

The present invention is a result of academic collaborations between University of Nevada Las Vegas (UNLV) and Peking University (PKU). The jointly effort of UNLV and PKU professors and postdocs is the key to the success.

### FIELD

The present invention is generally related to solid electrolyte compositions and devices such as sodium batteries and capacitors employing the Na-rich anti-perovskite compositions. The present invention is also related to the synthesis methods and processing methods of Na-rich anti-perovskite compositions for sodium batteries and capacitors utilities.

### BACKGROUND

Batteries with inorganic solid-state electrolytes have many advantages such as enhanced safety and cycling efficiency. All solid-state sodium ionic batteries are considered to be promising for next generation vehicles and large-scale energy storage. Currently available solid electrolytes for sodium batteries are NASICON-type ceramics and sulfides. However, they suffer from several drawbacks such as bad machinability, high-cost and inflammability.

### SUMMARY OF THE INVENTION

Solid electrolyte compositions provided herein can include sodium electrolyte compositions, such as Na-rich anti-perovskite (NaRAP) materials. NaRAP materials have favorable structure flexibility, which can allow various chemical manipulation techniques. NaRAP materials can have enhanced sodium transport rates, which can boost ionic conductivity. In some cases, solid electrolyte compositions provided herein can boost ionic conductivity to superionic levels. Solid electrolyte compositions provided herein can be used in rechargeable batteries to produce more affordable rechargeable batteries. Solid electrolyte compositions provided herein can be made using any suitable synthesis method and processed into a suitable configuration using any suitable processing method. Certain synthesis methods and processing methods provided herein can achieve high-purity phases with accurately controlled compositions having optimized performance in integrated devices. Certain synthesis methods and processing methods provided herein can be affordable and efficient.

Solid electrolyte compositions provided herein can include at least 10 atomic percent sodium. In some cases, NaRAP materials provided herein have at least 20 atomic percent sodium. In some cases, NaRAP materials provided herein have at least 30 atomic percent sodium. In some cases, NaRAP materials provided herein have at least 40 atomic percent sodium. In some cases, NaRAP materials provided herein have between 40 and 60 atomic percent sodium. In some cases, NaRAP materials provided herein have between 50 and 60 atomic percent sodium.

Solid electrolyte compositions provided herein can include NaRAP compositions having a formula of Na₃OX, Na₃SX, Na_{(3-δ)}M_{δ/2}OX and/or Na_{(3-δ)}M_{δ/2}SX, wherein 0<δ<0.8, wherein X is a monovalent anion selected from the group consisting of fluoride, chloride, bromide, iodide, H⁻, CN⁻, BF₄⁻, BH₄⁻, ClO₄⁻, CH₃⁻, NO₂⁻, NH₂⁻ and mixtures thereof, and wherein M is a divalent metal selected from the group consisting of magnesium, calcium, barium, strontium and mixtures thereof.

Electrochemical device provided herein can include that NaRAP compositions having a chemical formula Na₃OX, Na₃SX, Na_{(3-δ)}M_{δ/2}OX and/or Na_{(3-δ)}M_{δ/2}SX, wherein 0<δ<0.8, wherein X is a monovalent anion selected from the group consisting of fluoride, chloride, bromide, iodide, H⁻, CN⁻, BF₄⁻, BH₄⁻, ClO₄⁻, CH₃⁻, NO₂⁻, NH₂⁻ and mixtures thereof, and wherein M is a divalent metal selected from the group consisting of magnesium, calcium, barium, strontium and mixtures thereof.

Solid electrolyte compositions provided herein can, in some cases, have a formula of Na_{(3-δ)}M_{δ/3}OX and/or Na_{(3-δ)}M_{δ/3}SX; wherein 0<δ<0.5, wherein M is a trivalent cation M⁺³, (Al³⁺, Ga³⁺, In³⁺, Sc³⁺) and wherein X is a monovalent anion selected from the group consisting of fluoride, chloride, bromide, iodide, H⁻, CN⁻, BF₄⁻, BH₄⁻, ClO₄⁻, CH₃⁻, NO₂⁻, NH₂⁻ and mixtures thereof.

Synthesis and processing methods provided herein can result in Na-rich anti-perovskite solid electrolyte compositions in the form of fine powders, single crystals and films.

It should be understood that a device according to the present disclosure may include the disclosed compositions in any number of forms, e.g., as a film, as a single crystal slice, as a trace, or as another suitable structure. The disclosed materials may be disposed (e.g., via spin coating, pulsed laser deposition, lithography, or other deposition methods known to those of ordinary skill in the art) to a substrate or other part of a device. Masking, stencils, and other physical or chemical deposition techniques may be used so as to give rise to a structure having a particular shape or configuration.

In some cases, solid electrolyte compositions provided herein can be in the form of a film In some cases, a thickness of a film of solid electrolyte provided herein can be between about 0.1 micrometers to about 1000 micrometers. In some cases, a thickness of a film of solid electrolyte provided herein can have a thickness of about 10 micrometers to about 20 micrometers. In some cases, film and non-film structures comprising solid electrolyte compositions provided herein can having thicknesses of between 0.1 micrometers to about 1000 micrometers, between 1 micrometer and 100 micrometers, between 5 micrometers and 50 micrometers, or between 10 micrometers and 20 micrometers. For example, a device (e.g., a battery) provided herein can include a cathode, anode, electrolyte film having a thickness of between about 10 micrometers and about 20 micrometers. In some cases, a device provided herein can include a protective layer. In some cases, a protective layer on a device provided herein can be used to shield or otherwise protect components of the device, including the electrolyte. For example, suitable protective layers can include insulating substrates, semiconducting substrates, and even conductive substrates. Protective layers on devices provided herein can include any suitable material, such as SiO₂.

### BRIEF DESCRIPTION OF THE FIGURE DRAWINGS

The summary, as well as the following detailed description, is further understood when read in conjunction with the appended drawings. For the purpose of illustrating the disclosed technology, there are shown in the drawings exemplary embodiments; however, the disclosure is not limited to the specific methods, compositions, and devices disclosed. In addition, the drawings are not necessarily drawn to scale or proportion. In the figure drawings:

FIG. 1 is a representative anti-perovskite structure drawing of Na₃OX (X═F⁻, Cl⁻, Br⁻, I⁻, H⁻, CN⁻, BF₄⁻, BH₄⁻, ClO₄⁻, CH₃⁻, NO₂⁻, NH₂⁻, etc) to illustrate the 3-dimensional diffusion path of Na⁺. J₁ and J₂ are the two shortest Na—Na distance along [101] and [100] directions, respectively. The [ONa₆] or [SNa₆] octahedron is the basic building unit of an anti-perovskite structure.

FIG. 2 depicts a powder XRD pattern of the whole solid solutions of Na₃OCl₁₋ₓBrₓ (x=[0-1]), Na₃Br₁₋ₓIₓ (x=[0-0.5]) and divalent Ca²⁺, Sr²⁺ doped samples from top to bottom. The diffraction peaks of Na₃OCl are indexed in space group Pm-3m, a=4.496 Å. Asterisks indicate a small quantity of NaCl or NaBr impurities (<5% mol).

FIG. 3 depicts differential scanning calorimetry (DSC) curves of the representatives in anti-perovskites Na₃OX (X═Cl, Br, I) solid solution show that the Na-rich antiperovskite family is of low melting points allowing easy hot processing. The observed thermodynamic events (melting, crystallization, nucleation, possible A-site ordering and disordering) are marked accordingly.

FIG. 4 depicts impedance spectroscopy Nyquist plots of NaRAP. The real and imaginary components of the halogen-mixed Na₃OBr_{0.6}I_{0.4} and Sr-doped Na_{2.9}Sr_{0.05}OBr_{0.6}I_{0.4} measured at different temperatures.

FIG. 5 depicts arrhenius plots of log(ó) versus 1/T for pure Na₃OCl, Na₃OBr, halogen-mixed Na₃OBr_{0.6}I_{0.4} and alkali-earth ion doped Na_{2.9}Sr_{0.05}OBr_{0.6}I_{0.4} anti-perovskites. The activation energies Eₐ are derived by the slopes of the linear fitting of: ln(óT)=−Eₐ/kT.

### DETAILED DESCRIPTION

Na-rich electrolyte compositions provided herein can be used in a variety of devices (e.g., batteries). In some cases, sodium batteries can include a Na-rich electrolyte composition provided herein, which can provide enhanced sodium transfer rates as compared to other electrolyte compositions. In some cases, solid electrolyte compositions provided herein includes a material having a formula of Na₃OCl. In some cases,solid electrolyte compositions provided herein can include one or more materials having a general formula of Na₃OX, Na₃SX, Na_{(3-δ)}M_{δ/2}OX and/or Na_{(3-δ)}M_{δ/2}SX, wherein X is a monovalent anion selected from the group consisting of fluoride, chloride, bromide, iodide, H⁻, CN⁻, BF₄⁻, BH₄⁻, ClO₄⁻, CH₃⁻, NO₂⁻, NH₂⁻ and mixtures thereof, and M is an alkaline earth cation selected from Mg²⁺, Ca²⁺, Sr²⁺, Ba²⁺, and mixtures thereof. The value of δ in the formula is 0<δ<0.8. Some non-limiting values of δ include, 0.10, 0.15, 0.20, 0.25, 0.30, 0.35, 0.40, 0.45, 0.50, 0.55, 0.60, 0.65, 0.70, 0.75 and 0.80; δ may have a value smaller than 0.10. For example, some values of X that are less than 0.10 include 0.01, 0.02, 0.03, 0.04, 0.05, 0.06, 0.07, 0.08 and 0.09. For each of these values of δ, X is a halide or monovalent anion (H⁻, CN⁻, BF₄⁻, BH₄⁻, ClO₄⁻, CH₃⁻, NO₂⁻, NH₂⁻, etc), or mixture of them, and M is an alkaline earth cation, or a mixture of alkaline earth cations. X can be a mixture of chloride and bromide. X can be a mixture of chloride and fluoride. X can be a mixture of chloride and iodide. X can be a mixture of BF₄⁻ and a halide. X can be a mixture of chloride, bromide and iodide. It should be understood that X can be a mixture of any two halides, any three halides, all of four halides and also mixtures of monovalent anions (H⁻, CN⁻, BF₄⁻, BH₄⁻, ClO₄⁻, CH₃⁻, NO₂⁻, NH₂⁻).

In some cases, solid electrolyte compositions provided herein can be anti-perovskite. In some cases, solid electrolyte compositions provided herein can be anti-perovskite derivatives. An explanation of what is meant by an anti-perovskite may be better understood in relation to for following explanation of what a normal perovskite is. A normal perovskite has a composition of the formula ABO₃ wherein A is a cation Aⁿ⁺, B is a cation B⁽⁶⁻ⁿ⁾⁺ and O is oxygen anion O²⁻. Examples include K⁺Nb⁵⁻O₃, Ca²⁺Ti⁴⁺O₃, La³⁺Fe³⁺O₃. A normal perovskite is also a composition of the formula ABX₃, wherein A is a cation A⁺, B is a cation B²⁺ and X is an anion X⁻. Examples are K⁺Mg²⁺F₃ and Na⁺Mg²⁺F₃. A normal perovskite has a perovskite-type crystal structure, which is a well-known crystal structure, the dodecahedral center is regularly referred as A-site and the octahedral center is regularly referred as B-site.

In contrast to a normal perovskite, an anti-perovskite composition also has the formula ABX₃, but A and B are anions and X is the cation. For example, the anti-perovskite ABX₃ having the chemical formula ClONa₃ has a perovskite crystal structure but the A (e.g. Cl⁻) is an anion, the B (e.g. O²⁻) is an anion, and X (e.g. Na⁺) is a cation. Following the “cation-first” convention in the usual inorganic nomenclature of ionic compounds, we henceforth reverse the suggestive notation A⁻B²⁻A⁺₃ to the anti-perovskite notation defined as: X⁺₃B²⁻A⁻; thus, the Na-rich anti-perovskite (NaRAP) is denoted as Na₃OCl, which is an example of an anti-perovskite solid electrolyte composition provided herein.

Both Na₃OCl and Na_{2.9}Sr_{0.05}OCl are antiperovskites. The latter can be thought of relative to the former as having some of the sites that would have been occupied with Na⁺ now being replaced with the higher valence cation Sr²⁺. This replacement introduces vacancies in the anti-perovskite crystal lattice. Without being bound to any particular theory, it is believed that replacement of 2 Na⁺ with a Sr²⁺ introduces a vacancy in the antiperovskite crystal lattice. Impedance measurements show that Na_{2.9}Sr_{0.05}OCl (an exemplary composition) has a substantially higher ionic conductivity than Na₃OCl. It is believed that the creation of these vacancies by replacement a magnesium cation for two lithium cations, thus maintaining the charge balance, is responsible for the improved ionic conductivity of Na_{2.9}Sr_{0.05}OCl relative to Na₃OCl. It is believed that these vacancies facilitate Na⁺ hopping in the lattice.

In some cases, Na-rich anti-perovskite solid electrolyte compositions provided herein have a formula of Na₃OX, Na₃SX, Na_{(3-δ)}M_{δ/2} OX and/or Na_{(3-δ)}M_{δ/2}SX, wherein 0<δ<0.8 and X is a halide (F⁻, Cl⁻, Br⁻, I⁻ and mixtures thereof) or other monovalent anions (H⁻, CN⁻, BF₄⁻, BH₄⁻, ClO₄⁻, CH₃⁻, NO₂⁻, NH₂⁻, etc), and mixtures thereof, M is a cation with a 2+ charge (Mg²⁺, Ca²⁺, Sr²⁺, Ba²⁺ and mixtures thereof). In some cases, an anti-perovskite solid electrolyte composition provided herein can have a formula of Na_{(3-δ)}M_{δ/3}OX and/or Na_{(3-δ)}M_{δ/3}SX, wherein 0<δ<0.8 and M is a cation with a 3+ charge (e.g. Al³⁺, Ga³⁺, In³⁺, Sc³⁺), X is a monovalent anion (F⁻, Cl⁻, Br⁻, I⁻, H⁻, CN⁻, BF₄⁻, BH₄⁻, ClO₄⁻, CH₃⁻, NO₂⁻, NH₂⁻ and mixtures thereof).

It should be mentioned that, Na-rich anti-perovskite compositions stated here are not limited with typical cubic perovskite structure, but also perovskite-related structures. For example, distorted perovskite structures with low symmetries, structures comprising of anion centered XNa₆ octahedra units, are possible perovskite-related structures that Na-rich anti-perovskite compositions may adopt. In some cases, solid electrolyte compositions provided herein include at least 50 atomic percent sodium. In some cases, solid electrolyte compositions provided herein include up to 60 atomic percent sodium. In some cases, solid electrolyte compositions provided herein include between 50 atomic percent and 60 atomic percent sodium. In some cases, solid electrolyte compositions provided herein provide advantageous 3-dimensional diffusion paths generated by structure feature provided herein.

It should be mentioned that, Na-rich anti-perovskite compositions Na₃OX or Na₃SX stated here are not limited with O²⁻/S²⁻ anions exactly located in the B-sites and monovalent anions, such as F⁻, Cl⁻, Br⁻, I⁻, H⁻, CN⁻, BF₄⁻, BH₄⁻, ClO₄⁻, CH₃⁻, NO₂⁻ or NH₂⁻, in the A-sites. Both of the mono- and di-valent anions may occupy either A-sites or B-sites, or mixed distribution in them. This situation may happen especially when the ionic radiuses of the two anions are very close (r(S²⁻)=1.84 angstrom versus r(Cl⁻)=1.81 angstrom. For example, both Na₃SCl and Na₃ClS are Na-rich anti-perovskites electrode compositions provided herein. No matter which anion is situated at the A-site and/or at the B-site. They are the same.

Solid electrolyte compositions provided herein may be used as the electrolytes in sodium ionic batteries, capacitors and other electrochemical devices. These solid electrolytes provide advantages such as high stability, high safety and no leakage over more conventional gel-liquid systems. These crystalline solids can, in some cases,provide better machinability, low-cost and inflammability than the known Na-rich sulfides or NASICON-type ceramics.

Na-rich anti-perovskite electrolytes were prepared by using a direct solid state reaction method, sodium metal reduction method, solution precursor method or organic halides halogenations method. Na-rich anti-perovskite electrolyte films were processed by melting-and-coating method or vacuum splashing method.

Na-rich anti-perovskite electrolytes may be prepared by using a direct solid state reaction method. In an embodiment, Na₂O and NaCl (1:1 molar ratio) were mixed thoroughly in a glove box. Annealing at 200-400° C. followed by repeated grinding and heating several times provide the anti-perovskite electrolyte products. In another example, anhydrous Na₂S and NaCl (1:1 molar ratio) were mixed thoroughly in a glove box. Annealing at 200-400° C. followed by repeated grinding and heating several times provide the anti-perovskite electrolyte products Na₃SCl.

Na-rich anti-perovskite electrolytes may be prepared by using a sodium metal reduction method. In another example, NaOH and NaCl (1:1 molar ratio) were mixed thoroughly in air, then excessive Na metal (110% molar ratio) was added in the mixture in a glove box. Slow heating to 200° C. under vacuum and annealing at 200-400° C. followed by repeated grinding and heating several times provide the anti-perovskite electrolyte products.

Na-rich anti-perovskite electrolytes may be prepared by using solution precursor method. In another example, NaOH and NaCl (1:1 molar ratio) solutions were mixed together in air. After slow heating at 60, 80, 100, 150 and 200° C., excessive Na metal (110% molar ratio) was added in the mixture in a glove box. Slow heating to 200° C. under vacuum and annealing at 200-400° C. followed by repeated grinding and heating several times provide the anti-perovskite electrolyte products.

Na-rich anti-perovskite electrolytes may be prepared in a thin film platform by using solution precursor method. In another example, NaOH and NaCl (1:1 molar ratio) solutions were mixed together and concentrated in air. Then it was dipped or spreaded on various substrates including Al₂O₃, Al foil, Ag foil and Au foil. After slow heating at 60, 80, 100, 150 and 200° C., Na metal was splashed to the surface at moderated temperature. Slow heating to 200° C. under vacuum and annealing at 200-400° C. provide the anti-perovskite electrolyte films.

In a vacuum sputtering process and in a paused laser deposition (PLD) process, both the mixture of the raw reagents (Na₂O+NaX) and/or already-formed anti-perovskites (Na₃OX) can be used as starting materials. The final products are Na₃OX with anti-perovskite structure.

Various solvent including distilled water, methanol, ethanol, CCl₄, and their mixtures were used to provide Na-rich anti-perovskite electrolytes. In most embodiments, distilled water was used as a solvent.

High pressure techniques may be used to obtain some phases such as Na₃O(NH₂), Na₃O(BH₄), Na₃SCl and Na₃S(NO₂). The syntheses was monitored by in-situ and real-time synchrotron X-ray diffraction using a large volume PE cell at Beamline 16-BMB of the Advanced Photon Source (APS) at Argonne National Laboratory. An energy-dispersive X-ray method was employed with X-rays collected at a fixed Bragg angle of 2è=15°. The pressure was determined using a reference standard of MgO. The uncertainty in pressure measurements is mainly attributed to statistical variation in the position of diffraction lines of MgO and was typically less than 2% of the cited values. The pressure and temperature range are 1-7 GPa and 100-800° C., respectively.

The EXAMPLES below provide non-limiting embodiments of Na-rich anti-perovskite solid electrolyte compositions provided herein. For these EXAMPLES, analytical pure (AR) powders of NaCl, NaBr, NaI, NaBF₄, Na₂S, NaOH, Na₂O, CaO, SrO and Na metal were obtained from Alfa Aesar.

### EXAMPLE A

Preparation of Na₃OCl: 0.400 g NaOH and 0.585 g NaCl are weighted and ground together in N₂ atmosphere for several minutes. The resulting fine powder is paved on 0.253 g Na metal and the mixture is placed in an alumina crucible and then sealed in a quartz tube. The sample is firstly heated to 150° C. (past the melting point Tₘ=97.8° C. of Na metal) under vacuum at a heating rate of 1.5° C./min, then to 350° C. at a heating rate of 10° C./min. During heating process 1 mol reactant will release 0.5 mol H₂, so that caution and proper disposal must be taken when conduct the experiment and the total amount of the raw materials should be well schemed. After holding at the highest reacting temperature for 3 hours, the samples are cooled to room temperature naturally. Phase-pure powders of Na₃OCl can be obtained by repeating the grinding and heating processes for 3 times. The overall synthesis approach of a batch of samples costs about 24 hours.

Powder X-ray diffraction data were collected at room temperature (25° C.) on a Rigaku D/Max-2000 diffractometer using a rotating anode (Cu Kα, 40 kV and 100 mA), a graphite monochromator and a scintillation detector. Before measurements, the samples were enclosed in a laboratory film (PARAFILM “M”) under N₂ atmosphere to avoid moisture absorption. The film contributes to the whole XRD pattern at 21.7°, 24.0° and 74.9° as three small and distinct peaks, which can be easily eliminated in subsequent analyses. An X-ray diffraction pattern of the reaction product was dominated by the anti-perovskite Na₃OCl. While in some cases, additional and weaker diffraction lines also appeared that matched those for the unreacted raw materials NaCl or Na₂O (<5% by molar ratio). Usually, impurities can be avoided simply by repeat the grinding and heating processes.

The sodium ionic conductivity of the product Na₃OCl was obtained from electrochemical impedance measurements. The samples were melted within two gold foils (thickness: 100 μm) at about 280° C. in inert atmosphere, and followed by prolonged annealing at 230° C. to ensure sufficient contacting. The as-obtained pellets had a final diameter of ˜7 mm and thickness of about 0.3 mm. AC impedance measurements were then performed using an electrochemical work station analyzer (Zennium, Zahner) at frequencies ranging from 0.1 Hz to 4 MHz and a disturbance voltage of 5 mV. Since the materials are sensitive to moisture and become unstable with oxygen at elevated temperature, all of the measurements were made in dry N₂ atmosphere. The ionic conductivity of Na₃OCl was approximately 10⁻⁵ S/cm in the range of 150-200° C., and increased to 10⁻⁴ S/cm as the temperature increased above 250° C.

Compared with direct solid state reaction method (Na₂O+NaCl→Na₃OCl), excess Na metal (5%-10%) used in this procedure can eliminate the presence of OH⁻ in the lattice effectively and therefore the influence on sodium ionic conductivity. The overall reaction equation is listed as follows: Na+NaOH+NaX→Na₃OX+1/2H₂⇑.

### EXAMPLE B

Preparation of Na₃OBr_{0.5}I_{0.5}: 0.400 g NaOH, 0.515 g NaBr, and 0.645 g NaI are weighted and ground together in N₂ atmosphere for several minutes. The resulting fine powder is paved on 0.253 g Na metal and the mixture is placed in an alumina crucible and then sealed in a quartz tube. The sample is firstly heated to 150° C. (past the melting point Tₘ=97.8° C. of Na metal) under vacuum at a heating rate of 1.5° C./min, then to 350° C. at a heating rate of 10° C./min. After holding at the highest reacting temperature for 3 hours, the samples are cooled to room temperature naturally. Phase-pure powders of Na₃OBr_{0.5}I_{0.5} can be obtained by repeating the grinding and heating processes for 3 times. The overall synthesis approach of a batch of samples costs about 24 hours.

Powder X-ray diffraction data were collected at room temperature (25° C.). Before measurements, the samples were enclosed in a laboratory film (PARAFILM “M”) under N₂ atmosphere to avoid moisture absorption. An X-ray diffraction pattern of the reaction product was dominated by the anti-perovskite Na₃OBr_{0.5}I_{0.5}. The sodium ionic conductivity of the product Na₃OBr_{0.5}I_{0.5} was obtained from electrochemical impedance measurements. The samples were melted within two gold foils (thickness: 100 μm) at about 280° C. in inert atmosphere, and followed by prolonged annealing at 230° C. to ensure sufficient contacting. The as-obtained pellets had a final diameter of ˜7 mm and thickness of about 0.3 mm. AC impedance measurements were then performed using an electrochemical work station analyzer (Zennium, Zahner) at frequencies ranging from 0.1 Hz to 4 MHz and a disturbance voltage of 5 mV. The ionic conductivity of Na₃O Br_{0.5}I_{0.5} was approximately 10⁻⁴ S/cm in the range of 150-200° C., and increased to 10⁻³ S/cm as the temperature increased above 250° C.

### EXAMPLE C

Preparation of Na_{2.9}Sr_{0.05}OBr_{0.5}I_{0.5}: 0.360 g NaOH, 0.515 g NaBr, 0.645 g NaI and 0.052 g SrO are weighted and ground together in N₂ atmosphere for several minutes. The resulting fine powder is paved on 0.253 g Na metal and the mixture is placed in an alumina crucible and then sealed in a quartz tube. The sample is firstly heated to 150° C. (past the melting point Tₘ=97.8° C. of Na metal) under vacuum at a heating rate of 1.5° C./min, then to 350° C. at a heating rate of 10° C./min. After holding at the highest reacting temperature for 3 hours, the samples are cooled to room temperature naturally. Phase-pure powders of Na_{2.9}Sr_{0.05}OBr_{0.5}I_{0.5} can be obtained by repeating the grinding and heating processes for 3 times. The overall synthesis approach of a batch of samples costs about 24 hours.

Powder X-ray diffraction data were collected at room temperature (25° C.). Before measurements, the samples were enclosed in a laboratory film (PARAFILM “M”) under N₂ atmosphere to avoid moisture absorption. An X-ray diffraction pattern of the reaction product was dominated by the anti-perovskite Na_{2.9}Sr_{0.05}OBr_{0.5}I_{0.5}. The sodium ionic conductivity of the product Na_{2.9}Sr_{0.05}OBr_{0.5}I_{0.5} was obtained from electrochemical impedance measurements. The samples were melted within two gold foils (thickness: 100 μm) at about 280° C. in inert atmosphere, and followed by prolonged annealing at 230° C. to ensure sufficient contacting. The as-obtained pellets had a final diameter of ˜7 mm and thickness of about 0.3 mm. AC impedance measurements were then performed using an electrochemical work station analyzer (Zennium, Zahner) at frequencies ranging from 0.1 Hz to 4 MHz and a disturbance voltage of 5 mV. The ionic conductivity of Na_{2.9}Sr_{0.05}OBr_{0.5}I_{0.5} was approximately 10⁻³ S/cm in the range of 150-200° C., and increased to 10⁻² S/cm as the temperature increased above 250° C.

### EXAMPLE D

Preparation of Na₃SBr: 0.7806 g Na₂S and 1.029 g NaBr are weighted and ground together in N₂ atmosphere for several minutes. The resulting fine powder is placed in an alumina crucible and then sealed in a quartz tube. The sample is heated to 350° C. under vacuum at a heating rate of 10° C./min. After holding at the highest reacting temperature for 3 hours, the samples are cooled to room temperature naturally. Phase-pure powders of Na₃SBr can be obtained by repeating the grinding and heating processes for 3 times. The overall synthesis approach of a batch of samples costs about 24 hours.

Powder X-ray diffraction data were collected at room temperature (25° C.) on a Rigaku D/Max-2000 diffractometer using a rotating anode (Cu Kα, 40 kV and 100 mA), a graphite monochromator and a scintillation detector. Before measurements, the samples were enclosed in a laboratory film (PARAFILM “M”) under N₂ atmosphere to avoid moisture absorption. The film contributes to the whole XRD pattern at 21.7°, 24.0° and 74.9° as three small and distinct peaks, which can be easily eliminated in subsequent analyses. An X-ray diffraction pattern of the reaction product was dominated by the anti-perovskite Na₃SBr. While in some cases, additional and weaker diffraction lines also appeared that matched those for the unreacted raw materials NaBr or Na₂S (<5% by molar ratio). Usually, impurities can be avoided simply by repeat the grinding and heating processes.

The sodium ionic conductivity of the product Na₃SBr was obtained from electrochemical impedance measurements. The samples were melted within two gold foils (thickness: 100 μm) at about 280° C. in inert atmosphere, and followed by prolonged annealing at 230° C. to ensure sufficient contacting. The as-obtained pellets had a final diameter of ˜7 mm and thickness of about 0.3 mm. AC impedance measurements were then performed using an electrochemical work station analyzer (Zennium, Zahner) at frequencies ranging from 0.1 Hz to 4 MHz and a disturbance voltage of 5 mV. Since the materials are sensitive to moisture and become unstable with oxygen at elevated temperature, all of the measurements were made in dry N₂ atmosphere.

### EXAMPLE E

Preparation of Na₃SBr_{0.5}I_{0.5}: 0.7806 g Na₂S, 0.515 g NaBr, and 0.645 g NaI are weighted and ground together in N₂ atmosphere for several minutes. The resulting fine powder is placed in an alumina crucible and then sealed in a quartz tube. The sample is heated to 350° C. under vacuum at a heating rate of 10° C./min. After holding at the highest reacting temperature for 3 hours, the samples are cooled to room temperature naturally. Phase-pure powders of Na₃SBr_{0.5}I_{0.5} can be obtained by repeating the grinding and heating processes for 3 times. The overall synthesis approach of a batch of samples costs about 24 hours.

Powder X-ray diffraction data were collected at room temperature (25° C.). Before measurements, the samples were enclosed in a laboratory film (PARAFILM “M”) under N₂ atmosphere to avoid moisture absorption. An X-ray diffraction pattern of the reaction product was dominated by the anti-perovskite Na₃SBr_{0.5}I_{0.5}. The sodium ionic conductivity of the product Na₃SBr_{0.5}I_{0.5} was obtained from electrochemical impedance measurements. The samples were melted within two gold foils (thickness: 100 μm) at about 280° C. in inert atmosphere, and followed by prolonged annealing at 230° C. to ensure sufficient contacting. The as-obtained pellets had a final diameter of ˜7 mm and thickness of about 0.3 mm. AC impedance measurements were then performed using an electrochemical work station analyzer (Zennium, Zahner) at frequencies ranging from 0.1 Hz to 4 MHz and a disturbance voltage of 5 mV. The ionic conductivity of Na₃SBr_{0.5}I_{0.5} was approximately 5×10⁴ S/cm in the range of 150-200° C., and increased to 2×10⁻³ S/cm as the temperature increased above 250° C.

### EXAMPLE F

Preparation of Na₃O(BF₄): 0.400 g NaOH and 1.098 g NaBF₄are weighted and ground together in N₂ atmosphere for several minutes. The resulting fine powder is paved on 0.253 g Na metal and the mixture is placed in an alumina crucible and then sealed in a quartz tube. The sample is firstly heated to 150° C. (past the melting point Tₘ=97.8° C. of Na metal) under vacuum at a heating rate of 1.5° C./min, then to 350° C. at a heating rate of 10° C./min. After holding at the highest reacting temperature for 3 hours, the samples are cooled to room temperature naturally. Phase-pure powders of Na₃O(BF₄) can be obtained by repeating the grinding and heating processes for 3 times. The overall synthesis approach of a batch of samples costs about 24 hours.

Powder X-ray diffraction data were collected at room temperature (25° C.). Before measurements, the samples were enclosed in a laboratory film (PARAFILM “M”) under N₂ atmosphere to avoid moisture absorption. An X-ray diffraction pattern of the reaction product was dominated by the anti-perovskite Na₃OBF₄. The sodium ionic conductivity of the product Na₃O(BF₄) was obtained from electrochemical impedance measurements. The samples were melted within two gold foils (thickness: 100 μm) at about 280° C. in inert atmosphere, and followed by prolonged annealing at 230° C. to ensure sufficient contacting. The as-obtained pellets had a final diameter of ˜7 mm and thickness of about 0.3 mm. AC impedance measurements were then performed using an electrochemical work station analyzer (Zennium, Zahner) at frequencies ranging from 0.1 Hz to 4 MHz and a disturbance voltage of 5 mV.

### EXAMPLE G

Preparation of Na₃OBr_{0.5}(BF₄)_{0.5}: 0.400 g NaOH, 0.515 g NaBr and 0.549 g NaBF₄are weighted and ground together in N₂ atmosphere for several minutes. The resulting fine powder is paved on 0.253 g Na metal and the mixture is placed in an alumina crucible and then sealed in a quartz tube. The sample is firstly heated to 150° C. (past the melting point Tₘ=97.8° C. of Na metal) under vacuum at a heating rate of 1.5° C./min, then to 350° C. at a heating rate of 10° C./min. After holding at the highest reacting temperature for 3 hours, the samples are cooled to room temperature naturally. Phase-pure powders of Na₃OBr_{0.5}(BF₄)_{0.5} can be obtained by repeating the grinding and heating processes for 3 times. The overall synthesis approach of a batch of samples costs about 24 hours.

Powder X-ray diffraction data were collected at room temperature (25° C.). Before measurements, the samples were enclosed in a laboratory film (PARAFILM “M”) under N₂ atmosphere to avoid moisture absorption. An X-ray diffraction pattern of the reaction product was dominated by the anti-perovskite Na₃OBr_{0.5}(BF₄)_{0.5}. The sodium ionic conductivity of the product Na₃OBr_{0.5}(BF₄)_{0.5} was obtained from electrochemical impedance measurements. The samples were melted within two gold foils (thickness: 100 μm) at about 280° C. in inert atmosphere, and followed by prolonged annealing at 230° C. to ensure sufficient contacting. The as-obtained pellets had a final diameter of ˜7 mm and thickness of about 0.3 mm. AC impedance measurements were then performed using an electrochemical work station analyzer (Zennium, Zahner) at frequencies ranging from 0.1 Hz to 4 MHz and a disturbance voltage of 5 mV.

### EXAMPLE H

Preparation of Na₃S(NO₂) by using high-pressure and high-temperature method: An amount of 0.550 grams Na₂S, and amount of 0.690 grams of NaNO₂, which corresponds to a molar ratio of Na₂S:NaNO₂ of 1:1, were mixed and grinded in a glove box under a dry argon atmosphere. The powder was then enclosed inside a container with its cap sealed using high-performance SCOTCH TAPE®. The syntheses was monitored by in-situ and real-time synchrotron X-ray diffraction using a PE apparatus at Beamline 16-BMB of the Advanced Photon Source (APS) at Argonne National Laboratory. The powder was loaded into a high pressure cell that consisted of an MgO container of 1 millimeter inner diameter and 1 millimeter length also serving as the pressure scale and a graphite cylinder as a heating element. Then two MgO disks were used to seal the sample from interacting with the outside environments (i.e. the oxygen and moisture).

After the pressure cell was completely assembled, all air pathways on the pressure cell were covered by DUCO® cement to isolate the powders from moisture. Before removing the assembly from the glove box, the resulting as-finished pressure cell was placed into a capped plastic tube with both ends sealed by high-performance electrical tape. The pressure cell was removed from the plastic tube, placed into the PE cell, and rapidly pumped up to a pressure of about 0.5 GPa sample pressure. Typically, it took 2-5 minutes to set up the anvil pressure module into the hydraulic press and then pump the oil pressure up so as to reach a sample pressure condition of approximately 0.5 GPa. It was believed that these steps isolated the sample contents of the pressure cell from room air. After synchrotron X-ray diffraction data were collected at two different sample positions, the sample were compressed to higher pressure and then heated in a stepwise fashion from a temperature of 100° C. to 800° C. Synchrotron X-ray diffraction data were collected for both the sample and the MgO along the heating path at temperatures of 100° C., 200° C., 300° C., 400° C., 500° C., 550° C., 600° C., 650° C., 700° C., 750° C. and 800° C. The experiment was ended by cooling to room temperature and then decompression to ambient conditions. Afterward, diffraction data were collected on the recovered sample at two different sample conditions.

### EXAMPLE I

Preparation of Na₃OCl in lamellar single crystal form: 0.400 g NaOH and 0.585 g NaCl are weighted and ground together in N₂ atmosphere for several minutes. The resulting fine powder is paved on 0.253 g Na metal and the mixture is placed in an alumina crucible and then sealed in a quartz tube. The sample is firstly heated to 150° C. (past the melting point Tₘ=97.8° C. of Na metal) under vacuum at a heating rate of 1.5° C./min, then to 350° C. at a heating rate of 10° C./min. After holding at the highest reacting temperature for 3 hours, the samples are cooled to room temperature naturally. Phase-pure powders of Na₃OCl can be obtained by repeating the grinding and heating processes for 3 times. Then the powders are allowed to melt again and cooled to room temperature with a cooling rate of 3° C./hour. Lamellar single crystal of Na₃OCl (thickness 10-50 μm) can be obtained by mechanical separation.

The sodium ionic conductivity of the Na₃OCl single crystal was obtained from electrochemical impedance measurements. The samples were coated with Au film on both sides in inert atmosphere, and followed by annealing at 230° C. to ensure sufficient contacting. AC impedance measurements were then performed using an electrochemical work station analyzer (Zennium, Zahner) at frequencies ranging from 0.1 Hz to 4 MHz and a disturbance voltage of 5 mV.

Additional Discussion as the Followings.

As explained elsewhere herein, sodium ion batteries show great promise in large-scale electrical energy storage with highly lowered cost, charge-discharge rates, and cycling lifetimes. However, common fluid electrolytes consisting of sodium salts dissolved in solvents may be toxic, corrosive, or even flammable. Currently available solid electrolyte candidates (mainly sulfides and the NASICON-type ceramics) still suffer from several drawbacks such as bad machinability, high-cost, and inflammability. Na-rich anti-perovskite solid electrolytes with superionic conductivity at moderate temperature may avoid those shortcomings and be used with a metallic sodium anode, thereby allowing comparatively low cost and high safety.

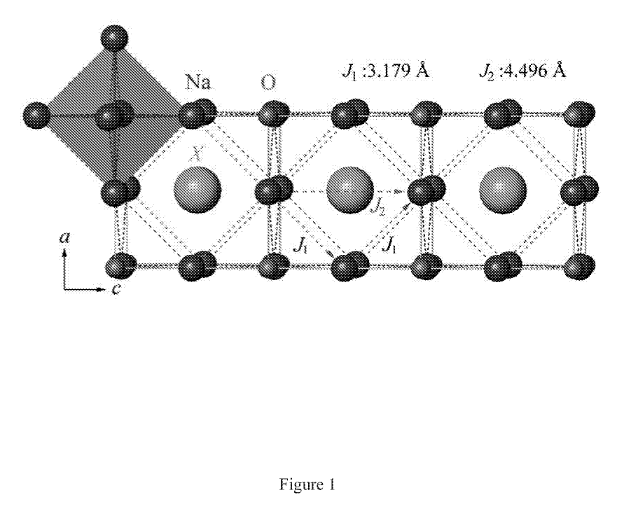

The present disclosure provides, inter alia, a new family of solid electrolytes with three-dimensional conducting pathways based on Na-rich anti-perovskites (NaRAP) (FIG. 1). The materials may, in some cases, exhibit ionic conductivity of, e.g., σ>10⁻³ S/cm at moderate temperature (e.g., 200° C.) and an activation energy of about 0.6 eV. As temperature approaches the melting point, the ionic conductivity of the anti-perovskites increases to advanced superionic conductivity of σ>10⁻²S/cm and beyond. Most importantly, the new crystalline materials can be readily manipulated via chemical and structural methods to boost ionic transport and serve as high-performance solid electrolytes for superionic sodium conduction in electrochemistry applications.

The present disclosure also provides a variety of synthesis techniques useful for synthesizing the disclosed materials. Solid state reaction is the most direct and convenient method to obtain Na-rich anti-perovskite composites. The equation may be:

Na₂O+NaCl→Na₃OCl

However, extreme care should be taken during the whole reaction period to avoid the presents of water or hydroxyl. While other synthetic methods adopting sodium metal or organic halides may avoid this problem easily. Take the “sodium metal reduction method” for example,excess Na metal (5%-10%) is used to eliminate the presence of OH⁻ in the lattice and therefore its influence on conductivity. The starting materials of Na₃OCl synthesis may comprise combining (e.g., mixing) together 1 equivalent of NaOH, 1 equivalent of NaCl and excess 1.1 equivalent Na metal. In an exemplary synthesis, firstly, NaOH and NaCl are ground together for several minutes with a mortar and pestle. Then the resulting powder may be placed on the top of the Na metal and slowly heated to 150° C. (i.e., past the melting point Tₘ=92° C. of Na metal) under vacuum, and finally heated quickly to about 350° C. for a period of time.

During heating, hydrogen is generated and pumped outside. It can be considered as a in situ method to produce fresh Na₂O by the following equation:

Na+NaOH→Na₂O+1/2H₂⇑

And the overall reaction equation is listed as follows:

Na+NaOH+NaCl→Na₃OCl+1/2H₂⇑

At the end of the reaction, the molten product in the quartz tube may be rapidly cooled (e.g., quenched) or slowly cooled to room temperature, which results in different textures and grain boundary morphologies. At the end of the synthesis, the apparatus is flushed with a dry inert gas (e.g., Ar, N₂, and the like) and the hygroscopic sample remains unexposed to atmospheric moisture.

Other reducers such as NaH can also be used to obtain Na₃OX without hydroxyl. The impact of them to eliminate hydroxyl follows the equation:

NaH+NaOH→Na₂O+H₂⇑

And the overall reaction equation is listed as follows:

NaH+NaOH+NaCl→Na₃OCl+H₂⇑

Sometimes, there are several intermediate phases [e.g. Na₂(OH)Cl] observed during the reaction process. Then NaH reacts with the intermediate phases to give the final anti-perovskite products. In such a two-step process, the reaction equations are:

NaOH+NaCl→Na₂(OH)Cl

Na₂(OH)Cl+NaH→Na₃OCl+H₂⇑

It seems that such a two-step reaction process is helpful for the achievement of pure anti-perovskite products. The reason may be that the intermediate phase Na₂(OH)Cl also adopts similar anti-perovskite structure with the final products.

At the end of the reaction, the molten product in the quartz tube may be rapidly cooled (e.g., quenched) or slowly cooled to room temperature. The apparatus is flushed with a dry inert gas (e.g., Ar, N₂, and the like) and the hygroscopic sample remains unexposed to atmospheric moisture.

More Na-rich anti-perovskite composites (e.g., Na₃SCl, Na₃OCl_{0.5}Br_{0.5}, Na_{2 9}Ca_{0.05}OCl, Na_{2.9}Ca_{0.05}OBr_{0.5}I_{0.5}) can be synthesized by replacing any components in Na₃OCl using the same or similar sintering method. Some respective equations are listed as follows:

Na₃SCl: Na₂S+NaCl→Na₃SCl

Na₃OCl_{0.5}Br_{0.5}: Na₂O+0.5NaCl+0.5NaBr→Na₃OCl_{0.5}Br_{0.5}

or Na+NaOH+0.5NaCl+0.5NaBr→Na₃OCl_{0.5}Br_{0.5}+1/2H₂⇑

Na_{2.9}Ca_{0.05}OCl: 0.95Na₂O+0.05CaO+NaCl→Na_{2.9}Ca_{0.05}OCl

or Na+0.05CaO+0.9NaOH+NaCl→Na_{2.9}Ca_{0.05}OCl

Na_{2.9}Ca_{0.05}OBr_{0.5}I_{0.5}: 0.95Na₂O+0.05CaO+0.5NaCl+0.5NaBr→Na_{2.9}Ca_{0.05}OBr_{0.5}I_{0.5}

or Na+0.05CaO+0.9NaOH+0.5NaCl+0.5NaBr→Na_{2.9}Ca_{0.05}OBr_{0.5}I_{0.5}+1/2H₂⇑

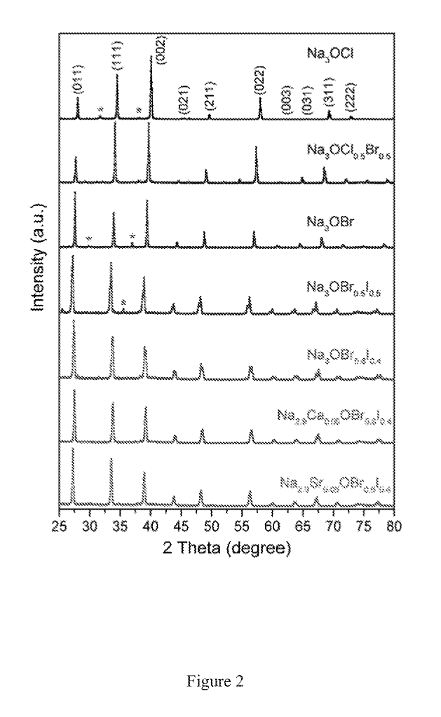

FIG. 2 shows the powder X-ray diffraction pattern of the Na-rich anti-perovskite composites. The products by halides-mixing and divalent-metal-dopping could be readily obtained with high purity and the main peaks could be indexed in cubic space group Pm-3m of the antiperovskite structure. One may combine the above-mentioned reactions to produce materials with more anti-perovskite compositions.

The sodium-rich anti-perovskite compositions may, in some cases, be hygroscopic and they may be advantageous to prevent their exposure to atmospheric moisture. Exemplary synthesis, material handling, and all subsequent measurements were performed in dry glove boxes with controlled dry inert atmosphere (Ar or N₂).

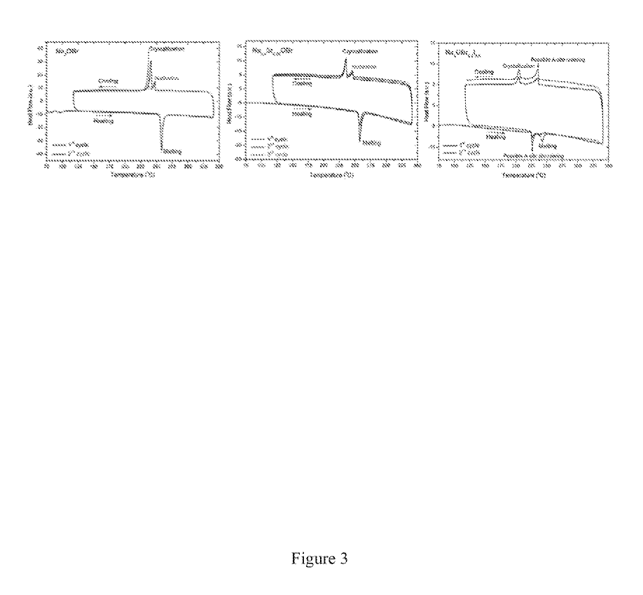

Thermal analysis approaches are employed to explore the subtle structural changes of the materials. The results are shown in FIG. 3. The NaRAP melt congruently at relative low temperatures, ca. 255° C. for Na₃OCl₁₋ₓBrₓ, and show tiny divergences between two end members of Na₃OCl, Na₃OBr, and their mixed solid solutions. During cooling, all of the samples show two distinct exothermic peaks, which may correspond to the possible slow-motion nucleation or ordering of the halogen ions and subsequent crystallization to the crystalline state. A small quantity of divalent alkali earth metal doping doesn't result in any obvious changes compare to its parent compound. Whereas, I⁻ ion mixing in the bromine isologues results in a notable lowering of melting point to about 240° C. for Na₃OBr_{0.5}I_{0.5}, before which a new endothermic peaks located at 226° C. representing possible A-site disordering in the antiperovskite structure. Upon cooling, the temperature interval between “nucleation” and crystallization of Na₃OBr_{0.5}I_{0.5} elongate to about 30° C., which may considered as not more nucleation than a possible Br⁻/I⁻ ordering within the A-site.

The NaRAP materials can circulate the melting and crystallization processes several times without decomposition, showing their potential facility for hot machining

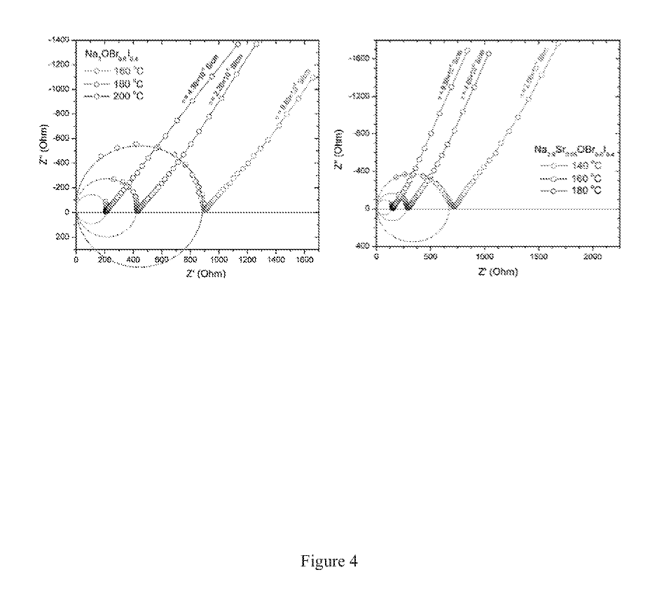

Na-rich anti-perovskite composites serving as promising solid electrolytes may greatly benefit from their flexible crystal structures for easily chemical manipulation. There are two previous reports on the ionic conductivity of anti-perovskite Na₃OBr and Na₃OCN but only giving low values under their melting points. This demonstrates that both halogen-mixing and alkali-earth metal doping can improve the ionic conducting performance remarkably. FIG. 4 shows the representative conductivity measurement results for the halogen-mixed and alkali-earth metal-doped Na₃OX solid solutions at moderate temperatures. The impedance plots consist of a semicircle and a spike, respectively corresponding to contributions from the grain of the crystalline electrolyte and an inter-electrode capacitance. The derived ionic conductivities for Na₃OBr_{0.6}I_{0.4} are 9.80×10⁻⁵ S/cm at 160° C., 2.26×10⁻⁴ S/cm at 180° C., and 4.30×10⁻⁴ S/cm at 200° C. When a spot of divalent Sr²⁺ ions were doped into the Na sites (Na_{2.9}Sr_{0.05}OBr_{0.6}I_{0.4}), the value can boost to 2.06×10⁻⁴ S/cm at 140° C., and 9.50×10⁻⁴ S/cm at 180° C.

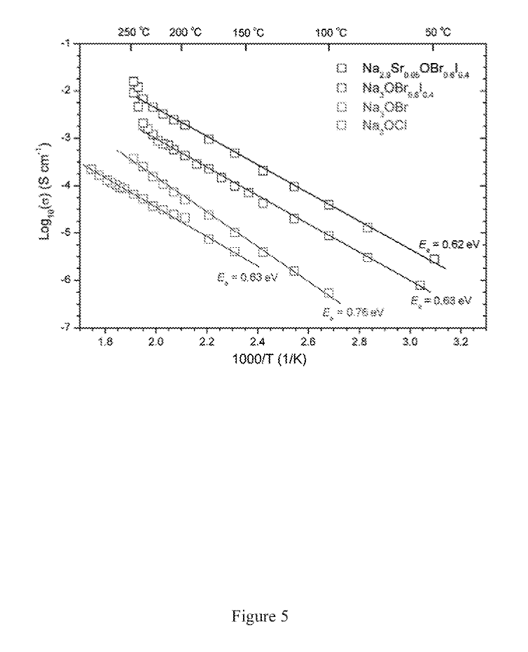

The activation energies for ionic conduction were calculated to be 0.76 eV for Na₃OBr and 0.63 eV for Na₃OBr_{0.6}I_{0.4} and 0.62 eV for Na_{2.9}Sr_{0.05}OBr_{0.6}I_{0.4}, respectively based on the formula: óT=A₀×exp(−Eₐ/kT), FIG. 5. They are much bigger than those in Li-rich antiperovskite superionic conductors (˜0.23 eV), reasonable considering the larger ionic radius of Na⁻ than Li⁺, but comparable with other typical sodium superionic conductors such as Na₃PS₄ and Na₃ZrSi₂PO₁₂.

FIG. 5 shows the Arrhenius plots of several representatives of the NaRAP materials. The sodium ionic conductivities increase from pure Na₃OCl to Na₃OBr and then to iodine-mixed Na₃OBr_{0.6}I_{0.4}, which may be attributed to the mismatching effect by the incorporation of bigger halogen ions in the A-sites. Alternate Br and I anions with diverse ionic radii in the dodecahedral A-sites within the three-dimensional lattice will provide much free space for the Na⁺ ions to hop in and pass through, via interstitial route(i.e., Frankel style). On the other hand, divalent Sr²⁺ doping in the Na⁺ sites will consequentially introduces more vacancies, which are essential to provide effectual diffusion pathway for high ionic conductivity (i.e., Schottky style). The optimized conductivity value in Na_{2.9}Sr_{0.05}OBr_{0.6}I_{0.4} is more than two magnitudes higher than those in pure Na₃OBr, and reaches 2.78×10⁻⁶ S/cm at room-temperature, 1.89×10⁻³ S/cm at 200° C., and even beyond 10⁻² S/cm when temperature approaches the melting point.

The impact of possible big anions (Cl⁻, Br⁻, I⁻) in the B-sites. It is generally considered that small divalent O²⁻/S²⁻ will occupy the octahedrally coordinated B-sites in an anti-perovskite structure. However, it is also possible for bigger halide anions occupying the B-sites and accordingly the O²⁻/S²⁻ anions in the A-sites, especially when their radiuses are close. The event may happen as partially mixed static distribution or fully reversed A-/B-sites occupation. The sodium ionic conductivity may benefit from the easier migration of sodium ions due to the weaker bonding between them and the monovalent anions.

The disclosed sodium-rich solid electrolytes based on the anti-perovskite offer a number of applications. For example, Na-rich anti-perovskites represent advances in electrochemistry systems as a cathode material that offers a variety of possible cation and/or anion manipulations. Indeed, the low melting point of the anti-perovskites enables the straightforward fabrication of thin films, which is useful in the fabrication of layered structures and components for high-performance battery/capacitor devices with existing technology. The anti-perovskites have a high sodium concentration; display superionic conductivity; and offer a comparatively large operation window in voltage and current. The products are lightweight and can be formed easily into sintered compacts. The disclosed anti-perovskites are readily decomposed by water to sodium hydroxide and sodium halides of low toxicity and are therefore completely recyclable and environmentally friendly. The low cost of the starting materials and easy synthesis of the products in large quantities present economic advantages as well. The Na-rich anti-perovskites thus represent a material capable of structural manipulation and electronic tailoring.

Although the present invention has been described with reference to specific details, it is not intended that such details should be regarded as limitations upon the scope of the invention, except as and to the extent that they are included in the accompanying claims.

What is claimed is:

1. A solid electrolyte composition comprising a material having a formula of Na₃OX, Na₃SX, or a combination thereof.

2. The solid electrolyte composition of claim 1, wherein X is a halide selected from fluoride, chloride, bromide, iodide and mixtures thereof.

3. The solid electrolyte composition of claim 1 or claim 2, wherein X is a monovalent anion, H⁻, CN⁻, BF₄⁻, BH₄⁻, ClO₄⁻, CH₃⁻, NO₂⁻, NH₂⁻ and mixtures thereof.

4. A solid electrolyte composition comprising a material having a formula of Na_{(3-δ)}M_{δ/2}OX, Na_{(3-δ)}M_{δ/2}SX, or a combination thereof.

5. The solid electrolyte composition of claim 4, wherein 0<δ<0.8.

6. The solid electrolyte composition of one of claim 4 or claim 5, wherein X is a halide selected from fluoride, chloride, bromide, iodide and mixtures thereof.

7. The solid electrolyte composition of one of claims 4-6, wherein M is selected from the group consisting of magnesium, calcium, strontium, barium, zinc, and mixtures thereof.

8. The solid electrolyte composition of one of claims 4-7, wherein X is a monovalent anion, H⁻, CN⁻, BF₄⁻, BH₄⁻, ClO₄⁻, CH₃⁻, NO₂⁻, NH₂⁻ and mixtures thereof.

9. A solid electrolyte composition comprising a material having a formula of Na_{(3-δ)}M_{δ/3}OX, Na_{(3-δ)}M_{δ/3}SX, or a combination thereof.

10. The solid electrolyte composition of claim 9, wherein 0<δ<0.8.

11. The solid electrolyte composition of claim 9 or claim 10, wherein X is a halide selected from fluoride, chloride, bromide, iodide and mixtures thereof.

12. The solid electrolyte composition of one of claims 9-11, wherein M is a trivalent cation M⁺³, (Al³⁺, Ga³⁺, In³⁺, Sc³⁺) and mixtures thereof.

13. An electrochemical device, comprising a solid electrolyte composition of one of claims 1-12.

14. The electrochemical device of claim 13, wherein said electrochemical device comprises a battery.

15. The electrochemical device of claim 13, wherein said electrochemical device comprises a capacitor.

16. A method of synthesizing a solid electrolyte composition of one of claims 1-12, wherein said method includes a synthesis method selected from the group consisting of direct solid state methods, sodium metal reduction method, solution precursor method, and organic halides halogenations method.

17. A method of processing a solid electrolyte composition of one of claims 1-12, comprising one or more processing methods selected from the group consisting of hot-spreading methods, solution precursor methods, and vacuum-splashing methods.

18. A solid electrolyte composition comprising a sodium anti-perovskite salt, the sodium anti-perovskite salt comprising at least 40 atomic percent sodium.

19. The solid electrolyte composition of claim 18, wherein the sodium anti-perovskite salt comprises between 50 and 60 atomic percent sodium.

20. The solid electrolyte composition of claim 18 or claim 19, wherein the sodium anti-perovskite salt has a formula of Na₃OX, Na₃SX, Na_{(3-δ)}M_{δ/2}OX, Na_{(3-δ)}M_{δ/2}SX, Na_{(3-δ)}M_{δ3}OX, Na_{(3-δ)}M_{δ/3}SX, or a combination thereof, wherein 0<δ<0.8, wherein X is a halide selected from fluoride, chloride, bromide, iodide and mixtures thereof, wherein M is selected from the group consisting of magnesium, calcium, strontium, barium, zinc, and mixtures thereof.
